(19) United States
(12) Patent Application Publication
(10) Pub. No.: US 2002/0070883 A1
(43) Pub. Date: Jun. 13, 2002

(54) Internet terminal and keyboard for the internet terminal

(75) Inventor: Franz A. Dosch, Rosenheim (DE)

Correspondence Address: MICHAEL BEST & FRIEDRICH, LLP, 100 E WISCONSIN AVENUE, MILWAUKEE, WI, 53202, US

(73) Assignee: Dosch & Amand GmbH & Co. KG, Muenchen (DE)

(21) Appl. No.: 09/909,471

(22) Filed: Jul. 19, 2001

(30) Foreign Application Priority Data
Jul. 25, 2000 (DE) 20012863.9

(51) Int. Cl. H03M 11/00; H03K 17/94

(52) U.S. Cl. 341/22

(57) ABSTRACT

A system (10) comprising an internet terminal (20) and a keyboard (30) adapted to be coupled therewith, wherein:

the internet terminal (20), which is preferably designed as a WebPad, comprises:

a touch-sensitive display (21),

a means (22) for coupling the keyboard (30),

a means (23) for communication with the keyboard (30), and

a means (24) for receiving power for operating the internet terminal (20) from the keyboard (30), and

the keyboard (30) comprises:

a plurality of keys (31) for receiving inputs from a user,

a means (32) for coupling the internet terminal (20), the means being designed such that the user can operate the keys (31) and simultaneously view the display (21),

a means (33) for communication with the internet terminal (20),

a means (34) for receiving power from a power supply system,

and a means (35) for supplying power to the internet terminal (20).

The present invention relates to an internet terminal and a keyboard for use with the internet terminal. In particular, the invention relates to a mobile internet terminal, hereinafter also called a WebPad.

A growing interest of computer users in the internet results in computers which are specifically adapted to the internet. These special computers, hereinafter also called internet terminals, are to enable a user to use the internet in a way which is as simple and intuitive as possible.

According to the prior art an internet terminal comprises e.g. a keyboard with specific keys or a computer mouse with an additional wheel, such means simplifying navigation in the internet. Other internet terminals according to the prior art comprise a touch-sensitive display permitting navigation by direct selection on the display. To take into account an increasing mobility of the users, internet terminals become portable and cordless. Such mobile internet terminals are compact and substantially flat and are therefore also designated as WebPads. Since for reasons of space, weight and above all costs such mobile internet terminals are often without a conventional keypad, a comfortable operation in the case of intensive writing activities is hardly possible. Furthermore, the power supply for a long operation is often inadequate. Moreover, means for storing large amounts of data and information in mobile internet terminals are considerably limited or do not exist at all for reasons of costs, size, weight and power consumption. Therefore, it is necessary for some users to buy both a stationary internet terminal and a mobile internet terminal.

It is therefore the object of the present invention to provide a system which permits a stationary, comfortable and long operation with a mobile internet terminal.

This object is achieved according to the invention with the subject matter of the independent claim 1. Preferred embodiments of the invention are the subject matters of the dependent claims.

According to a first aspect of the invention a system comprises an internet terminal and a keyboard adapted to be coupled therewith, wherein the internet terminal, which is preferably designed as a WebPad, comprises a touch-sensitive display, a means for coupling the keyboard, a means for communication with the keyboard, and a means for receiving power for operating the internet terminal from the keyboard, and the keyboard comprises a plurality of keys for receiving inputs from a user, a means for coupling the internet terminal, the means being designed such that the user can operate the keys and simultaneously view the display, a means for communication with the internet terminal, a means for receiving power from a power supply system, and a means for supplying power to the internet terminal.

According to a second aspect the communication between the internet terminal and the keyboard is without contact.

According to a third aspect power is supplied to the internet terminal and received from the keyboard without contact.

According to a fourth aspect the system further comprises a base station suited for connection to a telephone network, for wireless communication, preferably according to the DECT (Digital European Cordless Telecommunication) standard, the internet terminal further comprising a means for the wireless communication with the base station.

According to a fifth aspect the keyboard further comprises a means for storing power.

According to a sixth aspect the means for coupling the internet terminal comprises means which surround the coupled internet terminal laterally at least in part.

According to a seventh aspect the means for coupling the internet terminal comprises means which permit a pivoting of the internet terminal.

According to an eighth aspect a line of intersection of a first plane defined by the plurality of keys and of a second plane defined by the display substantially defines an axis around which the pivotal movement takes place.

According to a ninth aspect the means for coupling the internet terminal comprises means which maintain a relative position of the coupled internet terminal and the keyboard.

According to a tenth aspect the keyboard further comprises a means for storing large amounts of data, preferably a hard-disk drive.

According to an eleventh aspect the keyboard further comprises a means for reading in data and programs, preferably a CD-ROM disk drive, so that the operating software of the internet terminal can also be upgraded or updated via this means without any problems.

Advantages as well as preferred embodiments of the invention shall now be explained in more detail with reference to the attached drawings which show in detail in

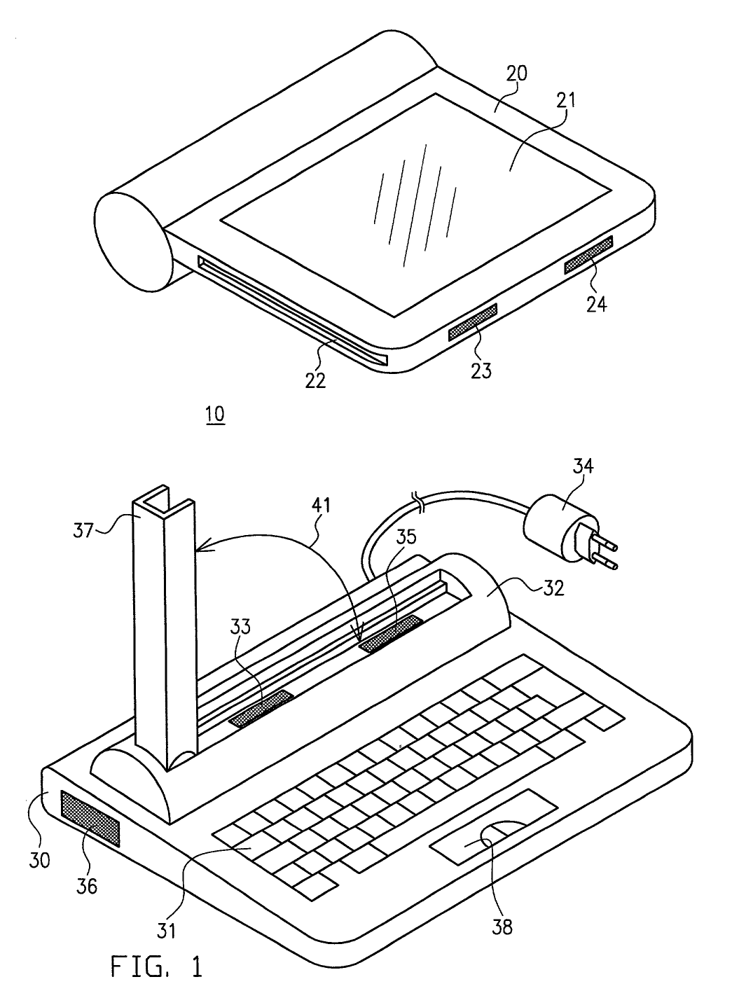

FIG. 1 a schematic representation of an internet terminal and a keyboard which are designed according to a preferred embodiment of the invention, and in

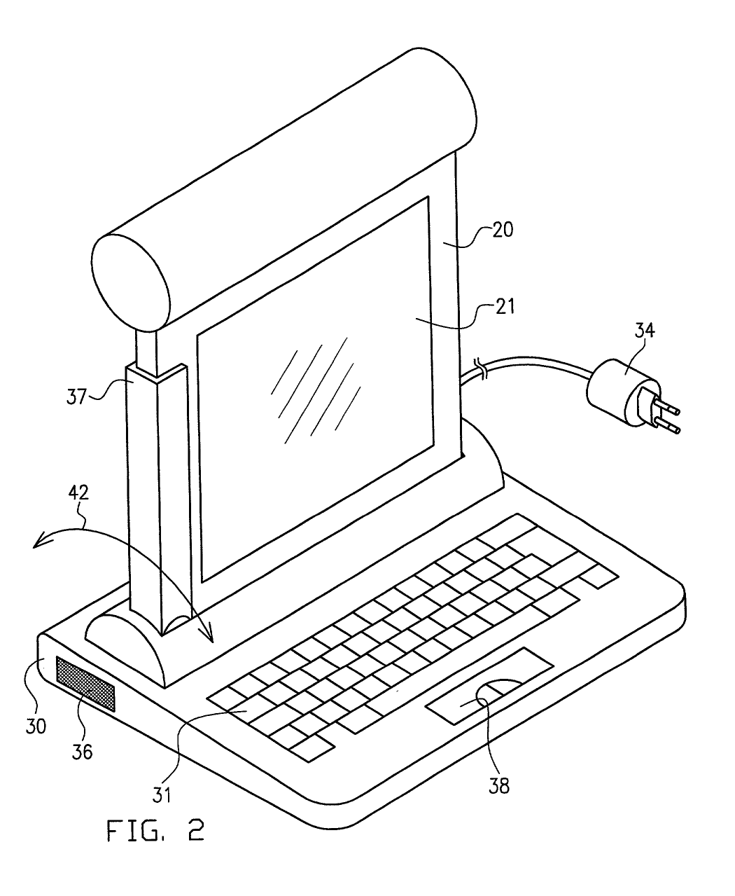

FIG. 2 a schematic representation of the internet terminal and the keyboard which are coupled according to the preferred embodiment.

FIG. 1 shows a system 10 comprising the internet terminal 20 and the keyboard 30 according to the preferred embodiment of the invention. The internet terminal 20 comprises a touch-sensitive display 21, a means 22 for coupling the keyboard 30, a means 23 for communication with the keyboard 30, and a means 24 for receiving power for operating the internet terminal 20 from the keyboard 30. As shown in FIG. 1, the touch-sensitive display 21 is surrounded in the manner of a frame by a housing of the internet terminal 20. Thus a user can place the internet terminal 20 in front of him, for instance on a table, and study the contents of the display 21. A slight inclination of the display 21 is possible by giving the housing a corresponding shape, whereby the readability of the display 21 can be improved.

The internet terminal 20 further comprises a processor and a memory. A non-volatile part of the memory accommodates an operating system, for instance based on Linux, and an internet browser. Preferably, the internet terminal 20 comprises an operating system which starts instantaneously (instant-on operating system). The internet terminal 20 further comprises a power supply which is preferably designed as an accumulator. Moreover, the internet terminal 20 may comprise a means for receiving operating power from an external power supply. Furthermore, the internet terminal 20 may comprise standard interfaces, preferably an interface of the USB (universal serial bus) standard for the connection of peripheral equipment, such as printers, disk drives and communication modems, a means for charging the accumulator, camera and other conventional computer means.

Furthermore, the internet terminal 20 may comprise a means for communication with a connectable identification module (subscriber information module, SIM), such as a contact-based chip card or a contactless transponder. Furthermore, the internet terminal 20 may comprise a means for communication with a communication network, the means serving as an interface between the internet terminal 20 and the communication network which permits a connection to the internet. The communication network may be a public fixed telephone network or a mobile telephone network. Alternatively, the internet terminal 20 may be connected via the means to a computer network, such as a local network (local-area network, LAN) or a wide-area network (WAN). The design of the means depends on the features of the respective communication network. The interface may be wire-bound or may be of the wireless type. The means may alternatively be a conventional serial, parallel or USB interface, or the like, and the connection to the, for instance, public fixed telephone network may be established via a modem. The public fixed network may either be an analog or a digital and, in particular, an ISDN telephone system.

The keyboard 30 is designed as a docking station and comprises a plurality of keys 31 for receiving inputs from a user, a means 32 for coupling the internet terminal 20, the means 32 being designed such that the user can press the keys 31 and simultaneously view the display 21, a means 33, preferably in accordance with the USB standard, for communication with the internet terminal 20, a means 34 for receiving power from a power supply system, the means 34 being preferably designed as a plug-in power supply, and a means 35 for supplying power to the internet terminal 20. As shown in FIG. 1, the keys 31 which are arranged in a standard keypad for computers are surrounded by a housing of the keyboard 30 in the manner of a frame. The means 32 for coupling the internet terminal 20 is next to an upper edge of the keypad. The keyboard 30 is substantially flat and advantageously permits ergonomic writing.

The keyboard 30 may further comprise a power supply 36 which is preferably designed as an accumulator. The keyboard 30 may further comprise a touch pad 38.

The keyboard 30 may further contain a means for storing and fetching large amounts of data which expand the operability and performance of the internet terminal 20. Such data memories are preferably hard-disk drives for storing and reading data and CD-ROM disk drives for reading data. The latter can also be used for upgrading or updating operating software of the internet terminal.

The means 32 for coupling the internet terminal 20 is suited for partly receiving the internet terminal 20. Preferably, the means 32 is designed such that it receives or at least partly surrounds a part of the housing of the internet terminal 20 that is adjacent to a lower edge of the display 21. To this end the shape of the means 32 for coupling the internet terminal 20 and that of the part of the housing are matched to one another. The internet terminal 20 and the keyboard 30 can preferably be snapped onto one another for coupling purposes. Furthermore, the means 32 for coupling the internet terminal 20 preferably comprises means 37 which surround a coupled internet terminal 20 laterally at least in part. In the preferred embodiment these means 37 are designed as a pivot arm which can be folded in a space-saving manner into the means 32 intended for coupling in the direction of movement 41. The pivot arm is designed such that it is connectable to the means 22 of the internet terminal 20 for coupling the keyboard 30. To this end the shapes of the pivot arm and of the means 22 for coupling the keyboard 30 are matched to one another.

The means 23 of the internet terminal 20 for communication with the keyboard 30 and the means 33 of the keyboard 30 for communication with the internet terminal 20 can be interconnected without contact or with contact. A contactless communication is e.g. possible by way of an optical or inductive coupling. The means 23 and 33 are preferably arranged in the internet terminal 30 and the keyboard, 30, respectively, in such a manner that they face one another when the internet terminal 20 is coupled with the keyboard 30. Alternatively, the communication may be wireless, i.e. by means of radio waves.

The means 24 of the internet terminal 20 for receiving power for operating the internet terminal 20 from the keyboard 30 and the means 35 of the keyboard 30 for supplying power to the internet terminal 20 are interconnectable without contact or by way of contact. A contactless transmission is e.g. possible by inductive coupling. The means 24 and 35 are preferably arranged in the internet terminal 20 and the keyboard 30, respectively, in such a way that they face one another when the internet terminal 20 is coupled with the keyboard 30.

The internet terminal 20 and the keyboard 30 may comprise further means for mutual communication. In the preferred embodiment the communication with the communication network may selectively take place via the keyboard 30, so that e.g. a wireless communication takes place between the internet terminal 20 and a base station of the communication network when the internet terminal 20 is not coupled with the keyboard 30, and a wire-bound communication takes place between the keyboard 30 and the communication network when the internet terminal 20 is coupled with the keyboard 30.

FIG. 2 shows the system 10 in the coupled state of the internet terminal 30 and the keyboard 30. The means 32 of the keyboard 30 for coupling the internet terminal 20 surrounds the lower part of the housing of the internet terminal 20. The pivot arm 37 of the keyboard 30 additionally surrounds a lateral (here: left) part of the housing of the internet terminal 20. Alternatively, the internet terminal 20 may comprise guides which are preferably located in the interior of the internet terminal 20 and receive corresponding arms which belong to the means 32 of the keyboard 30 for coupling the internet terminal 20.

The means 23 of the internet terminal 20 for communication with the keyboard 30 and the means 33 of the keyboard 30 for communication with the internet terminal 20 can communicate with one another. This data interface is preferably of the USB standard and serves, on the one hand, the transmission of keyboard signals to the internet terminal, with the signals influencing the contents of the display 21, and, on the other hand, the transmission of data from the communication network (via the base station) to the memory means (in the receiving mode) or the transmission of data from the memory means into the communication network (in the transmitting mode). The means 24 of the internet terminal 20 for receiving power for operating the internet terminal 20 from the keyboard 30 and the means 35 of the keyboard 30 for supplying power to the internet terminal 20 can transmit power from the keyboard 30 to the internet terminal 20.

The means 32 of the keyboard 30 for coupling the internet terminal 20 is preferably designed such that the internet terminal 20 is pivotable in the direction of movement 42 about an axis which is substantially defined by a line of intersection of a first plane determined by the plurality of keys 31 and of a second plane determined by the display 21. Thus an optimum viewing angle onto the display 21 can be set. Furthermore, the means 32 of the keyboard 30 for coupling the internet terminal 20 comprises means which maintain a relative position of the coupled internet terminal 20 and of the keyboard 30. The system 10 can be adapted individually to the ergonomic needs of a user.

Thus the system 10 provides an adequate internet terminal which permits a comfortable operation, also during intensive writing, and, when equipped with a memory means, also permits the storage of information and their later retrieval. By decoupling the internet terminal 20 and the keyboard 30, the user will again obtain a mobile internet terminal 20 which can be operated via the touch-sensitive display 21.

1. A system (10) comprising an internet terminal (20) and a keyboard (30) adapted to be coupled therewith, wherein:
the internet terminal (20), which is preferably designed as a WebPad, comprises:
a touch-sensitive display (21),
a means (22) for coupling the keyboard (30),
a means (23) for communication with the keyboard (30), and
a means (24) for receiving power for operating the internet terminal (20) from the keyboard (30), and
the keyboard (30) comprises:
a plurality of keys (31) for receiving inputs from a user,
a means (32) for coupling the internet terminal (20), the means being designed such that the user can operate the keys (31) and simultaneously view the display (21),
a means (33) for communication with the internet terminal (20),
a means (34) for receiving power from a power supply system,
and a means (35) for supplying power to the internet terminal (20).

2. The system (10) according to claim 1, wherein the communication between the internet terminal (20) and the keyboard (30) takes place without contact.

3. The system (10) according to claim 1 or 2, wherein power is supplied to the internet terminal (20) and received from the keyboard (30) without contact.

4. The system (10) according to any one of claims 1 to 3, further comprising:
a base station suited for connection to a telephone network, for
wireless communication, preferably according to the DECT standard, wherein
the internet terminal (20) further comprises:
a means (25) for wireless communication with the base station.

5. The system (10) according to any one of claims 1 to 4, wherein the keyboard (30) further comprises:
a means (36) for storing power.

6. The system (10) according to any one of claims 1 to 5, wherein the means (32) for coupling the internet terminal (20) comprises means (37) which surround the coupled internet terminal (20) laterally at least in part.

7. The system (10) according to any one of claims 1 to 6, wherein the means (32) for coupling the internet terminal (20) comprises means which permit a pivoting of the internet terminal (20).

8. The system (10) according to claim 7, wherein a line of intersection of a first plane defined by the plurality of keys (31) and of a second plane defined by the display (21) substantially defines an axis around which the pivotal movement takes place.

9. The system (10) according to any one of claims 1 to 8, wherein the means (32) for coupling the internet terminal (20) comprises means which maintain a relative position of the coupled internet terminal (20) and of the keyboard (30).

10. The system (10) according to any one of claims 1 to 9, wherein the keyboard (30) further comprises:
a means for storing large amounts of data, preferably a hard-disk drive.

11. The system (10) according to any one of claims 1 to 10, wherein the keyboard (30) further comprises:
a means for reading in data and programs, preferably a CD-ROM disk drive.

12. An internet terminal (20) for use in the system according to any one of claims 1 to 11.

13. A keyboard (30) for use in the system (10) according to any one of claims 1 to 11.
